(19) United States
(12) Patent Application Publication
(10) Pub. No.: US 2023/0368964 A1
(43) Pub. Date: Nov. 16, 2023

(54) INDUCTOR COMPONENT

(71) Applicant: Murata Manufacturing Co., Ltd., Kyoto (JP)

(72) Inventors: Yoshimasa YOSHIOKA, Nagaokakyo-shi (JP); Yuuichi HIGUCHI, Nagaokakyo-shi (JP)

(73) Assignee: Murata Manufacturing Co., Ltd., Kyoto (JP)

(21) Appl. No.: 18/296,237

(22) Filed: Apr. 5, 2023

(30) Foreign Application Priority Data
May 10, 2022 (JP) 2022-077713

(51) Int. Cl. H01F 27/28; H01L 23/64; H01F 27/32; H01F 27/29

(52) U.S. Cl. CPC H01F 27/2823; H01L 23/645; H01F 27/323; H01F 27/29

(57) ABSTRACT

An inductor component comprising a semiconductor substrate made from a semiconductor material, the semiconductor substrate having a main surface; and a first inductor wire extending through the interior of the semiconductor substrate along the main surface. The first inductor wire contains the semiconductor material. Also, the first inductor wire has an electrical resistance lower than that of the semiconductor substrate and is integrated with the semiconductor substrate.

### CROSS REFERENCE TO RELATED APPLICATION

This application claims benefit of priority to Japanese Patent Application 2022-077713, filed May 10, 2022, the entire content of which is incorporated herein by reference.

### BACKGROUND

### Technical Field

The present disclosure relates to an inductor component.

### Background Art

A conventional inductor component is described in JP 6024243 B2. The inductor component includes a substrate having two main surfaces confronting each other, and two inductor wires formed on the main surfaces by electrolytic plating. The substrate is a common printed circuit board made from glass cloth impregnated with epoxy resin.

In the prior art, however, the inductor wires are formed on the main surfaces of an organic insulating substrate such as the printed circuit board by electroplating, so that the thickness of the inductor component increases.

### SUMMARY

Accordingly, the present disclosure provides an inductor component with a reduced thickness.

An inductor component of an aspect of the present disclosure comprises a semiconductor substrate made from a semiconductor material, the semiconductor substrate having a main surface; and a first inductor wire extending through the interior of the semiconductor substrate along the main surface. The first inductor wire contains the semiconductor material. Also, the first inductor wire has an electrical resistance lower than that of the semiconductor substrate and is integrated with the semiconductor substrate.

As used herein, the semiconductor material refers e.g. to a single semiconductor composed of a group IV element such as Si, a semiconductor composed of a group III compound or a group V compound such as GaAs, SiC, GaN, or InP, and an oxide semiconductor such as indium tin oxide (ITO).

According to the aspect, due to the extension of the first inductor wire through the interior of the semiconductor substrate, the thickness of the inductor component can be reduced as compared with the case where the first inductor wire is disposed above the semiconductor substrate.

Preferably, an embodiment of the inductor component further comprises an insulating layer disposed on the main surface.

According to the embodiment, the semiconductor substrate can be protected.

Preferably, in an embodiment of the inductor component, when viewed from a direction orthogonal to the main surface, the insulating layer lies inside of an outer edge of the main surface.

According to the embodiment, when separated into individual inductor components, the insulating layer can be restrained from coming into contact with a cutting blade. Then, a resin of the insulating layer cannot be clogged over the cut line of the cutting blade. This facilitates separation into individual inductor components.

Preferably, an embodiment of the inductor component further comprises an external terminal electrically connected to the first inductor wire, wherein the external terminal has a terminal main surface parallel to the main surface.

According to the embodiment, due to the disposition of the external terminal having a terminal main surface parallel to the main surface of the semiconductor substrate, the inductor component can easily be mounted onto a motherboard, a package substrate, or the like.

Preferably, in an embodiment of the inductor component, when viewed from a direction orthogonal to the main surface, the external terminal lies inside of an outer edge of the main surface.

According to the embodiment, when separated into individual inductor components, a cutting blade is restrained from coming into contact with the external terminal, so that deformation of the external terminal and the occurrence of burrs can be suppressed.

Preferably, an embodiment of the inductor component further comprises an overlayer partly covering an outer surface of the external terminal.

According to the embodiment, plating on the external terminal can easily be made.

Preferably, an embodiment of the inductor component further comprises a first connecting wire made from a metal material. The first connecting wire extends in a direction orthogonal to the main surface, to connect the external terminal and the first inductor wire.

According to the embodiment, the first connecting wire connects directly to the first inductor wire. This enables the external terminal to connect to the first inductor wire through a shortest path, achieving a reduction in electrical resistance.

Preferably, in an embodiment of the inductor component, the first connecting wire has an electrically non-conductive central portion.

According to the embodiment, resin or the like can be arranged at the central portion of the first connecting wire. This can relieve the stress on the first connecting wire.

Preferably, in an embodiment of the inductor component, the first connecting wire has an electrically conductive central portion made from an electroconductive material. The electroconductive material of the central portion differs from that of an outer peripheral portion covering an outer circumference of the central portion.

According to the embodiment, the first connecting wire can easily be produced.

Preferably, in an embodiment of the inductor component, a part of the first inductor wire in its extension direction has a wire width different from that of the other portions.

The embodiment can increase the freedom of design of the first inductor wire. This facilitates obtainment of a small-sized inductor component or an inductor component with large inductance.

Preferably, an embodiment of the inductor component further comprises a second inductor wire disposed above the main surface. The second inductor wire is made from a metal material, and the second inductor wire electrically connected to the first inductor wire.

The embodiment can increase the inductance since the inductor wiring portion of the inductor component can have elongated wiring length. Since the second inductor wire is made from metal, the resistivity of the inductor wiring portion can be restrained from increasing even though the inductor wiring portion has elongated wiring length.

Preferably, an embodiment of the inductor component further comprises a second connecting wire made from a metal material. The second connecting wire extends in a direction orthogonal to the main surface, and the second connecting wire connects the first inductor wire and the second inductor wire.

The embodiment allows direct connection of the second connecting wire to the first inductor wire. This enables the first and the second inductor wires to be connected together through a shortest route, achieving reduced electrical resistance.

Preferably, in an embodiment of the inductor component, the second connecting wire has an electrically non-conductive central portion.

The embodiment enables resin or the like to be arranged at the central portion of the second connecting wire. This can relieve the stress on the second connecting wire.

Preferably, in an embodiment of the inductor component, the second wire has an electrically conductive central portion made from an electroconductive material. The electroconductive material of the central portion differs from that of an outer peripheral portion covering an outer circumference of the central portion.

The embodiment facilitates production of the second connecting wire.

Preferably, an embodiment of the inductor component comprises a plurality of the first inductor wires, a plurality of the second inductor wires, and a plurality of the second connecting wires. The first inductor wire, the second connecting wire, and the second inductor wire are connected in the mentioned order, to make up a coil whose winding axis is parallel to the main surface.

This embodiment can restrain magnetic flux generated by the coil to intrude into the semiconductor substrate. This leads to improvement in Q factor.

Preferably, an embodiment of the inductor component further comprises a magnetic layer made from a magnetic material. The magnetic layer is disposed above the first inductor wire.

The embodiment achieves improvement in inductance and Q factor.

Preferably, in an embodiment of the inductor component, the first inductor wire extends in a spiral shape.

The embodiment ensures increase in inductance and reduction in thickness of the inductor component.

Preferably, an embodiment of the inductor component further comprises an insulating portion made from the semiconductor material turned into an insulator.

Due to the increased electrical resistance of the semiconductor substrate, the embodiment ensures reduction in eddy currents and improvement in Q factor.

Preferably, in an embodiment of the inductor component, the first inductor wire is at least partly silicidized.

The embodiment achieves further reduction in the electrical resistance of the first inductor wire.

According to the inductor component of an aspect of the present disclosure, the thickness can be reduced.

### BRIEF DESCRIPTION OF DRAWINGS

FIG. 1 is a top plan view showing a first embodiment of an inductor component;

FIG. 2 is a cross-sectional view taken along line II of FIG. 1;

FIG. 3 is a top plan view showing a second embodiment of the inductor component;

FIG. 4A is a cross-sectional view taken along line IVA of FIG. 3;

FIG. 4B is a cross-sectional view taken along line IVB of FIG. 3;

FIG. 5A is an explanatory view explaining a method for producing the inductor component;

FIG. 5B is an explanatory view explaining the method for producing the inductor component;

FIG. 5C is an explanatory view explaining the method for producing the inductor component;

FIG. 5D is an explanatory view explaining the method for producing the inductor component;

FIG. 5E is an explanatory view explaining the method for producing the inductor component;

FIG. 5F is an explanatory view explaining the method for producing the inductor component;

FIG. 5G is an explanatory view explaining the method for producing the inductor component;

FIG. 5H is an explanatory view explaining the method for producing the inductor component;

FIG. 5I is an explanatory view explaining the method for producing the inductor component;

FIG. 5J is an explanatory view explaining the method for producing the inductor component;

FIG. 5K is an explanatory view explaining the method for producing the inductor component;

FIG. 5L is an explanatory view explaining the method for producing the inductor component;

FIG. 6 is a cross-sectional view showing a third embodiment of the inductor component;

FIG. 7 is a cross-sectional view showing a fourth embodiment of the inductor component;

FIG. 8 is a cross-sectional view showing a fifth embodiment of the inductor component;

FIG. 9A is a cross-sectional view showing a variant of the inductor component;

FIG. 9B is a cross-sectional view showing another variant of the inductor component;

FIG. 9C is a cross-sectional view showing a further variant of the inductor component; and

FIG. 10 is a top plan view showing a sixth embodiment of the inductor component.

### DETAILED DESCRIPTION

An inductor component of an aspect of the present disclosure will now be described in detail with reference to shown embodiments. The drawings include schematics and may not reflect actual dimensions or ratios.

### First Embodiment

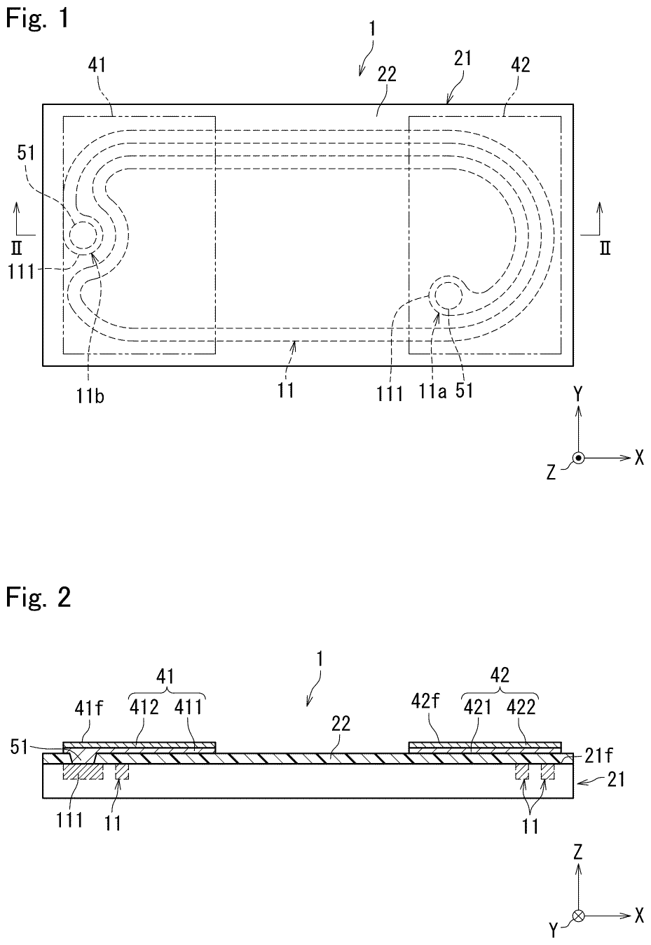

FIG. 1 is a top plan view showing a first embodiment of an inductor component. FIG. 2 is a cross-sectional view taken along line II-II of FIG. 1.

An inductor component 1 is mounted, for example, on electronic equipment such as a personal computer, a DVD player, a digital camera, a TV set, a cellular phone, and car electronics, and is a component of, for example, a generally rectangular parallelepiped shape. The shape of the inductor component 1 is not particularly limited and may be a cylindrical shape, a polygonal columnar shape, a truncated conical shape, or a polygonal truncated conical shape.

As shown in FIGS. 1 and 2, the inductor component 1 includes: a semiconductor substrate 21 having a main surface 21f, made from a semiconductor material; a first inductor wire 11 extending through the interior of the semiconductor substrate 21 along the main surface 21f; an insulating layer 22 disposed on the main surface 21f; and a first external terminal 41 and a second external terminal 42 that are disposed on the insulating layer 22. In FIG. 1, for convenience, the first external terminal 41 and the second external terminal 42 are indicated by double-dotted chain lines.

In the figures, let Z direction be a direction of thickness of the inductor component 1, with forward Z direction and reverse Z direction designating upper side and lower side, respectively, of the inductor component 1. Let X direction and Y direction be directions of length and width, respectively, of the inductor component 1 in a plane orthogonal to Z direction of the inductor component 1. “Above the main surface” refers to a direction toward the outside between the outside and inside of the substrate bounded by the main surface, not one absolute direction like “vertically above” defined by the direction of gravity. “Above the main surface” is therefore a relative direction defined by the orientation of the main surface. The same applies to “above the insulating layer”. “Above” an element includes not only a position directly above (on), in contact with, the element, but also a position apart upward from the element, i.e., an upper position via another object on the element or an upper position spaced apart from the element.

The semiconductor substrate 21 is made from a semiconductor material such as, for example, Si or other element semiconductor, GaAs, SiC, GaN, InP, or other compound semiconductor, or ITO or other oxide semiconductor. The semiconductor substrate 21 is preferably made from Si. Although the shape of the semiconductor substrate 21 is not particularly limited, it is a rectangular parallelepiped shape in this embodiment. The main surface 21f is a surface facing forward Z direction, of six surfaces making up the external surface of the semiconductor substrate 21.

The first inductor wire 11 is a wire spirally extending along the main surface 21f. This can increase the inductance and reduce the thickness of the inductor component 1. In this embodiment, the top surface of the first inductor wire 11 constitutes a part of the main surface 21f. It is preferred that the number of turns of the wire 11 exceed one turn. This leads to an increase in the inductance. When viewed from Z direction for example, the first inductor wire 11 is spirally wound in a clockwise direction from an outer peripheral end 11b to an inner peripheral end 11a. The first inductor wire 11 includes a pad portion 111 disposed on each of the outer peripheral end 11b and the inner peripheral end 11a. The pad is circular when viewed from Z direction. The diameter of the pad portion 111 is greater than the wire width of a wound portion that is a portion other than the pad portion 111 of the first inductor wire 11.

The first inductor wire 11 contains a semiconductor material of the semiconductor substrate 21 and has an electrical resistance lower than that of the semiconductor substrate 21, the first inductor wire 11 is integrated with the semiconductor substrate 21. In other words, the first inductor wire 11 contains a semiconductor material of the semiconductor substrate 21 and has a lower electrical resistance than the semiconductor substrate 21, the first inductor wire 11 is formed continuously with the semiconductor substrate 21. In cases where the semiconductor substrate 21 is made from e.g. Si, the first inductor wire 11 contains Si, and more specifically, contains Si doped with phosphorus or boron. In cases where the semiconductor substrate 21 is made from e.g. GaAs, the first inductor wire 11 contains Ga and As.

It is preferred that the first inductor wire 11 have an electrical resistivity sufficiently lower than that of the semiconductor substrate 21. Specifically, it is preferred that the electrical resistivity of the first inductor wire 11 be equal to or less than 1/1000 times the electrical resistivity of the semiconductor substrate 21. This enables most of current to flow through the first inductor wire 11, achieving suppression of inductance loss. For example, in cases where the semiconductor substrate 21 is made from Si, the electrical resistivity of the semiconductor substrate 21 is of the order of 10³ Ω·cm, so that it is preferred that the electrical resistivity of the first inductor wire 11 be equal to or less than 10⁻¹ Ω·cm. The electrical resistivity of the first inductor wire 11 can be figured out, for example, as follows. First, measuring probes are brought into contact with both ends of the first inductor wire 11, to measure the DC electrical resistance with the 4-terminal method. Next, the measured electrical resistance is multiplied by the cross-sectional area of the first inductor wire, i.e., the doped cross-sectional area which is doped with phosphorus or boron, and the obtained product is divided by the length between the both ends of the first inductor wire 11, so that the electrical resistivity can be measured. The doped cross-sectional area can be calculated by exposing a cross section across the first inductor wire 11 and then element-mapping the exposed cross section by energy dispersive X-ray (EDX) analysis. Specifically, in the element mapping, the doped cross-sectional area can be an area of the range having 30% or more of the peak doping amount.

The first inductor wire 11 may be formed by doping an impurity into the main surface 21f of the semiconductor substrate 21 to form a high-concentration impurity region. This allows the first inductor wire 11 to: contain the semiconductor material of the semiconductor substrate 21; have a lower electrical resistance than the semiconductor substrate 21; and become integrated with the semiconductor substrate 21. In cases where the semiconductor substrate 21 is made from Si, it is preferable to perform group III or group V impurity doping of the order of 1×10²⁰/cm³. In consequence, the electrical resistivity of the first inductor wire 11 becomes of the order of 10⁻¹ Ω·cm in the case of doping with phosphorus that is a group V impurity, while it becomes of the order of 5×10⁻³ Ω·cm in the case of boron that is a group III impurity.

The insulating layer 22 is made from, for example: an organic resin such as epoxy resin, phenol resin, polyimide resin, liquid-crystal polymer, or a combination thereof; a sintered body of glass, alumina, or the like; or a thin film such as silicon oxide film, silicon nitride film, or silicon oxynitride film. The insulating layer 22 can protect the semiconductor substrate 21 from the outside.

The outer peripheral end 11b of the first inductor wire 11 is connected, via a via wire 51 in contact with its top surface, to the first external terminal 41. The inner peripheral end 11a of the first inductor wire 11 is connected, via a via wire 51 in contact with its top surface, to the second external terminal 42. The via wire 51 is disposed within the insulating layer 22 and extends through the insulating layer 22 in a direction orthogonal to the main surface 21f. The via wire 51 is made of a metal material, for example, a low-resistance metal material such as Cu. Due to the above configuration, the via wire 51 is in direct contact with the first inductor wire 11. This enables the first and second external terminals 41 and 42 to connect to the first inductor wire 11 through a shortest path, achieving a reduction in electrical resistance. The via wire 51 corresponds to “first connecting wire” described in claims.

The first external terminal 41 and the second external terminal 42 are each made from an electroconductive material. In this embodiment, the first external terminal 41 and the second external terminal 42 include Cu plating layers 411 and 421, respectively, and Au plating layers 412 and 422, respectively, that are respectively stacked in the mentioned order. Without being limited to this configuration, the first external terminal 41 and the second external terminal 42 may each include a Cu layer with low electrical resistance and excellent stress resistance, an Ni layer with excellent corrosion resistance, and an Au layer with excellent solder wettability and reliability, which are stacked in the mentioned order. The Cu/Ni/Au layers have thicknesses of e.g. 5/5/0.01 μm, respectively. The first external terminal 41 is disposed such that it has a terminal main surface 41f parallel to the main surface 21f above the insulating layer 22 disposed on the main surface 21f of the semiconductor substrate 21, while the second external terminal 42 is disposed such that it has a terminal main surface 42f parallel to the main surface 21f above the insulating layer 22 disposed on the main surface 21f of the semiconductor substrate 21. The terminal main surfaces 41f and 42f are main surfaces of the first and second external terminals 41 and 42, respectively, located opposite to the main surface 21f of the semiconductor substrate 21. This facilitates mounting of the inductor component 1 onto a motherboard, a package substrate, or the like.

According to the inductor component 1, due to the extension of the first inductor wire 11 through the interior of the semiconductor substrate 21, the thickness of the inductor component 1 can be reduced as compared with the case where the first inductor wire 11 is disposed above the semiconductor substrate 21.

Preferably, when viewed from the direction (Z direction) orthogonal to the main surface 21f, the first and second external terminals 41 and 42 lie inside of the outer edge of the main surface 21f. According to this configuration, when separated into individual inductor components 1, a cutting blade is restrained from coming into contact with the first and second external terminals 41 and 42, so that deformation of the first and second external terminals 41 and 42 and the occurrence of burrs can be suppressed.

Preferably, the via wire 51 has an electrically non-conductive central portion. This configuration enables e.g. resin to be arranged at the central portion of the via wire 51. This can alleviate stress on the via wire 51.

Preferably, the via wire 51 has an electrically conductive central portion, with the electroconductive material of the central portion being different from the electroconductive material of the outer peripheral portion covering the outer circumference of the central portion. This configuration facilitates production of the via wire 51.

Preferably, the via wire 51 extends in the direction orthogonal to the main surface 21f, with the thickness of the via wire 51 in the direction orthogonal to the main surface 21f being greater than the thickness of the first inductor wire 11 in the direction orthogonal to the main surface 21f. The thickness of the via wire 51 and the thickness of the first inductor wire 11 in the direction orthogonal to the main surface 21f are measured on a cross section orthogonal to the main surface 21f passing through a center axis of the via wire 51, e.g. as shown in FIG. 2. For the thickness of the first inductor wire 11 in the direction orthogonal to the main surface 21f, the cross-sectional area doped with the impurity is calculated, for example, by exposing the cross section across the first inductor wire 11 and then element mapping it with EDX. Calculated as the thickness at this time is the range having 30% or more of the peak value of the doping amount graphed out in the thickness direction. The thickness of the first inductor wire 11 in the direction orthogonal to the main surface 21f is, for example, 15 μm.

Preferably, a part of the first inductor wire 11 in its extension direction has a wire width different from that of other part. The above “a part of the first inductor wire 11 in its extension direction” and “other part” exclude the pad portion 111. This configuration adds to the freedom of design of the first inductor wire 11. This facilitates obtainment of a small-sized inductor component 1 or an inductor component 1 with large inductance.

Preferably, the thickness of the inductor component 1 in Z direction is 100 μm or less. This configuration enables increase in the freedom to choose the mounting location of the inductor component 1. The inductor component 1 has, for example, a 0.4 mm of length in X direction, a 0.2 mm of width in Y direction, and a 50 μm of thickness in Z direction.

### Second Embodiment

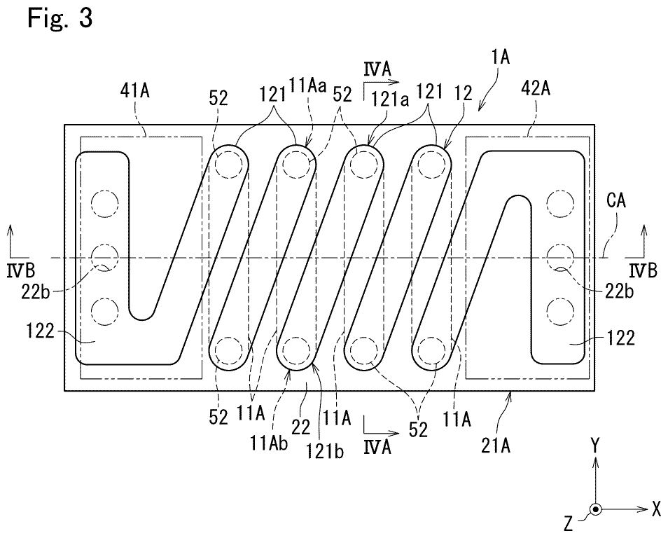

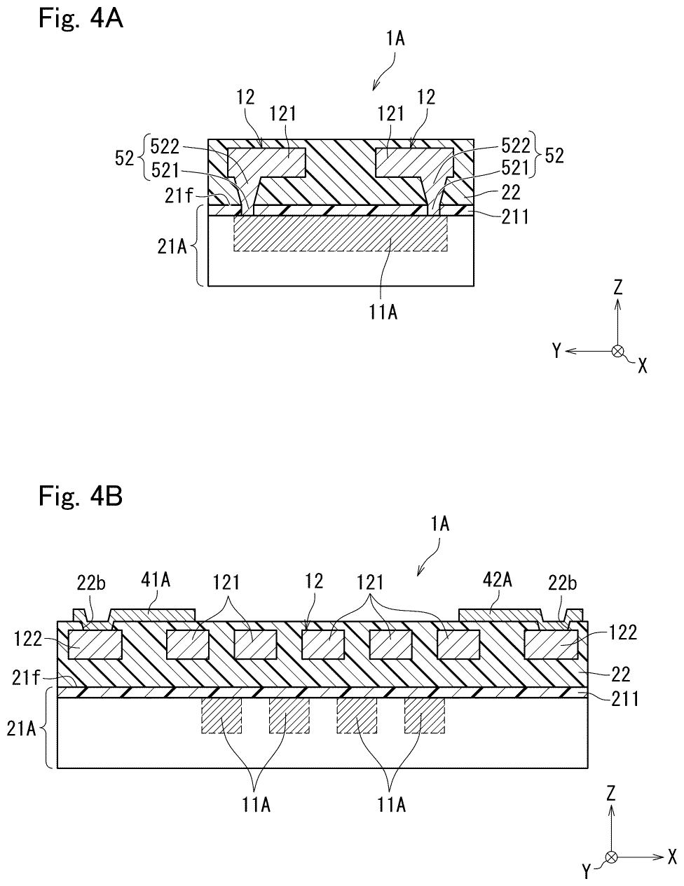

FIG. 3 is a top plan view showing a second embodiment of the inductor component. FIG. 4A is a cross-sectional view taken along line IVA-IVA of FIG. 3. FIG. 4B is a cross-sectional view taken along line IVB-IVB of FIG. 3. The second embodiment differs from the first embodiment mainly in the configuration of the semiconductor substrate and the shape of the first inductor wire and in that a second inductor wire is disposed. These different configurations will be described below. In the second embodiment, the same reference numerals as in the first embodiment designate the same configuration elements as those in the first embodiment and therefore will not again be described.

### Configuration

As shown in FIGS. 3, 4A, and 4B, an inductor component 1A includes: a semiconductor substrate 21A having a main surface 21f; a plurality of first inductor wires 11A extending through the interior of the semiconductor substrate 21A along the main surface 21f; a second inductor wire 12 disposed within the insulating layer 22 above the main surface 21f; a plurality of second connecting wires 52 disposed partly within the insulating layer 22; and a first external terminal 41A and a second external terminal 41B that are disposed on the insulating layer 22. In FIG. 3, for convenience, the first external terminal 41A and the second external terminal 41B are indicated by double-dotted chain lines.

The semiconductor substrate 21A disposed above the main surface 21f includes an insulating portion 211 of a semiconductor material turned into an insulator. The insulating portion 211 is made from e.g. a thermal silicon oxide (SiO₂) formed by thermally oxidizing the semiconductor substrate 21A. The top surface of the insulating layer 22 has openings 22b that are open to allow the top surface at both ends of the second inductor wire 12 to be partly exposed.

The first inductor wires 11A extend along the main surface 21f. Specifically, the first inductor wires 11A each extend rectilinearly from a first end 11Aa to a second end 11Ab in reverse Y direction. The top surface of each of the first inductor wire 11A is in contact with the underside of the insulating portion 211. The first inductor wires 11A are arranged in parallel along X direction. Similar to the first embodiment, the first inductor wires 11A contain a semiconductor material of the semiconductor substrate 21A and has an electrical resistance lower than that of the semiconductor substrate 21A, the first inductor wires 11 being integrated with the semiconductor substrate 21A.

The second inductor wire 12 includes a plurality of wiring portions 121 and two pad portions 122. The second inductor wire 12 is made from a metal material, for example, a low-resistance metal material such as Cu. The wiring portions 121 each extend rectilinearly from a first end 121a to a second end 121b in reverse Y direction with a slight tilt in X direction. The wiring portions 121 are arranged in parallel along X direction. The pad portions 122 each extend rectilinearly in Y direction. Each of the pad portions 122 is formed wider than each of the wiring portions 121. The pad portion 122 on one hand of the two pad portions 122 is connected to the first end 121a of the wiring portion 121 located on the farthest forward X direction side. The pad portion 122 on the other is connected to the second end 121b of the wiring portion 121 located on the farthest reverse X direction side. The first end 121a of the wiring portion 121 is connected via the second connecting wire 52 to the first end 11Aa of the first inductor wire 11A. The second end 121b of the wiring portion 121 is connected via the second connecting wire 52 to the second end 11Ab of the first inductor wire 11A. By the above configuration, the first inductor wire 11A, the second connecting wire 52, and the wiring portion 121 of the second inductor wire 12 are connected in the mentioned order so that there is formed a coil with a winding axis parallel to the main surface 21f, i.e., a helical coil whose spiral progresses along the winding axis. In this embodiment, a central axis CA as the winding axis of the coil is parallel to the main surface 21f of the semiconductor substrate 21A. This can suppress intrusion of magnetic flux generated by the coil into the semiconductor substrate 21A, enabling improvement in Q factor. The second inductor wire 12 may be a two-layer structure of a seed layer and an electrolytic plating layer or may contain Ti or Ni as the seed layer.

In this embodiment, the second connecting wire 52 is a vertical wire extending in the direction (Z direction) orthogonal to the main surface 21f of the semiconductor substrate 21. The second connecting wire 52 includes: a cylindrical via wire 521 disposed on the top surface of the first inductor wire 11A, extending through the insulating portion 211; and an inverted truncated conical shaped wire 522 in contact with the underside of the wiring portion 121, extending through the insulating layer 22 in forward Z direction from the top surface of the via wire 521. The above configuration allows the second connecting wire 52 to be in directly contact with the first inductor wire 11A. This enables the first inductor wire 11A and the second inductor wire 12 to connect to each other through a shortest path, so that the electrical resistance can be reduced.

The first external terminal 41A and the second external terminal 42A are each made from an electroconductive material, each being e.g. a two-layer structure of Ni and Au that are stacked in the mentioned order. The first external terminal 41A and the second external terminal 42A are disposed so as to cover the openings 22b, respectively, of the insulating layer 22. In consequence, the first external terminal 41A is connected to the pad portion 122 on one hand of the second inductor wire 12, while the second external terminal 42A is connected to the pad portion 122 on the other of the second inductor wire 12.

According to this embodiment, the disposition of the second inductor wire 12 enables increase in the wiring length of the inductor wiring portion of the inductor component 1A. This leads to increased inductance. Since the second inductor wire 12 is made from metal, the inductor wiring portion can be restrained from having increased resistivity in spite of having a longer wiring length.

In JP 6024243 B2, the inductor wiring is disposed on both the main surfaces of the organic insulating substrate. This is because, if the inductor wiring is disposed only on one main surface, problems such as substrate warping occur. In this embodiment, the substrate is a semiconductor substrate. The semiconductor substrate such as a silicon substrate is harder than the organic insulating substrate. For this reason, even though the second inductor wire 12 is disposed above the substrate, there is no need to dispose the second inductor wire 12 on both the main surfaces of the substrate taking the substrate warp, etc. into consideration. This results in suppression of increase in thickness of the inductor component 1A.

Preferably, the inductor component 1A further includes a magnetic layer made from a magnetic material, above the first inductor wire 11A. Specifically, the insulating layer 22 is preferably the magnetic layer made from a magnetic material. This configuration achieves improvement in inductance and Q factor.

### Production Method

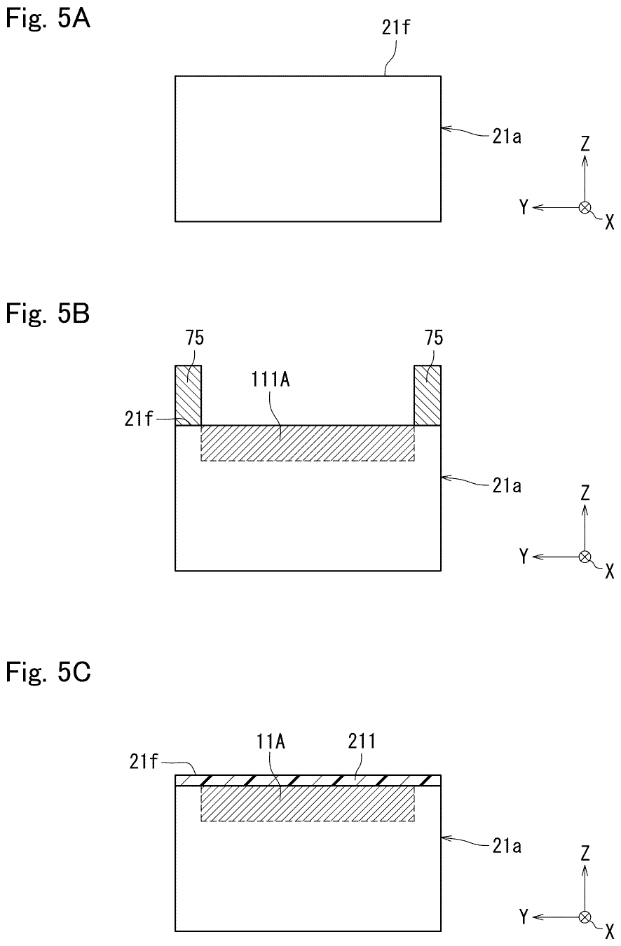

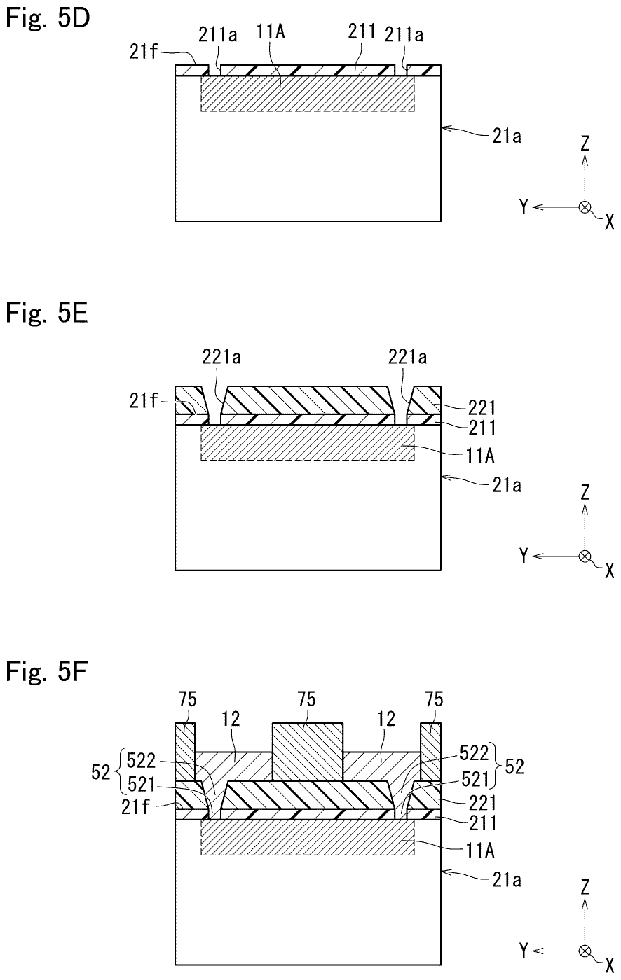

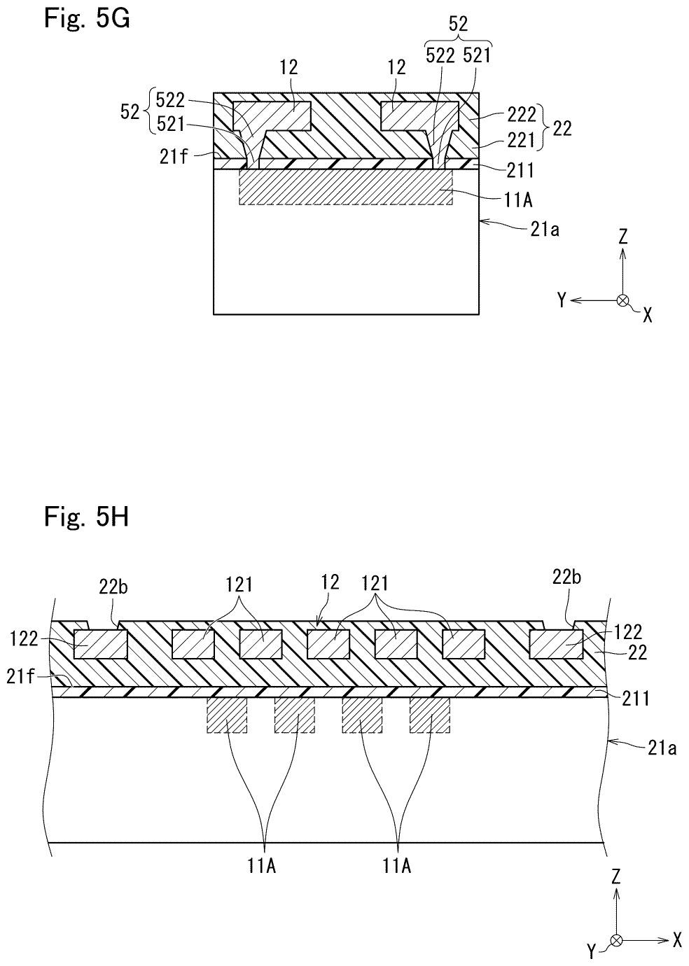

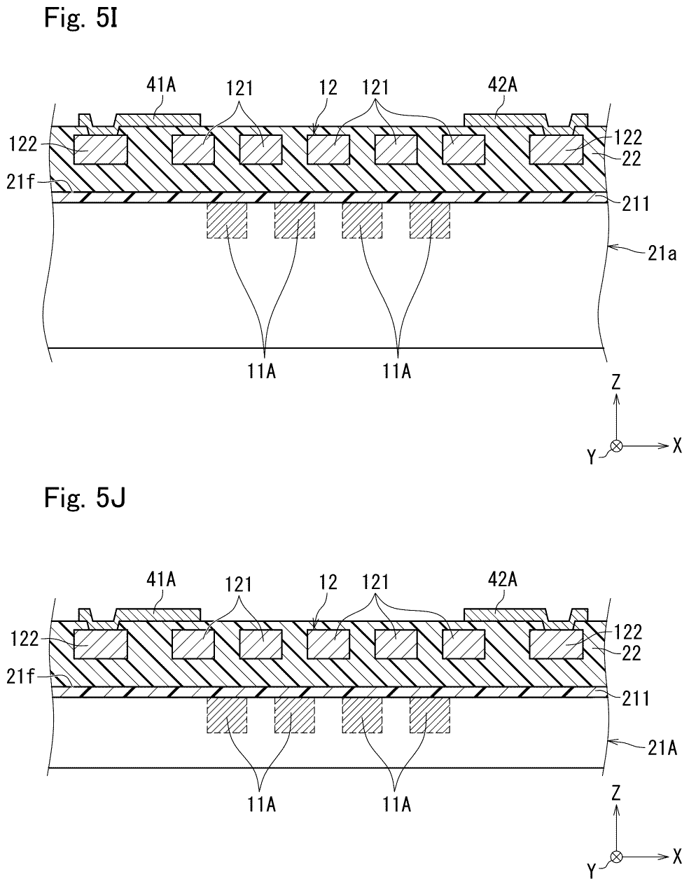

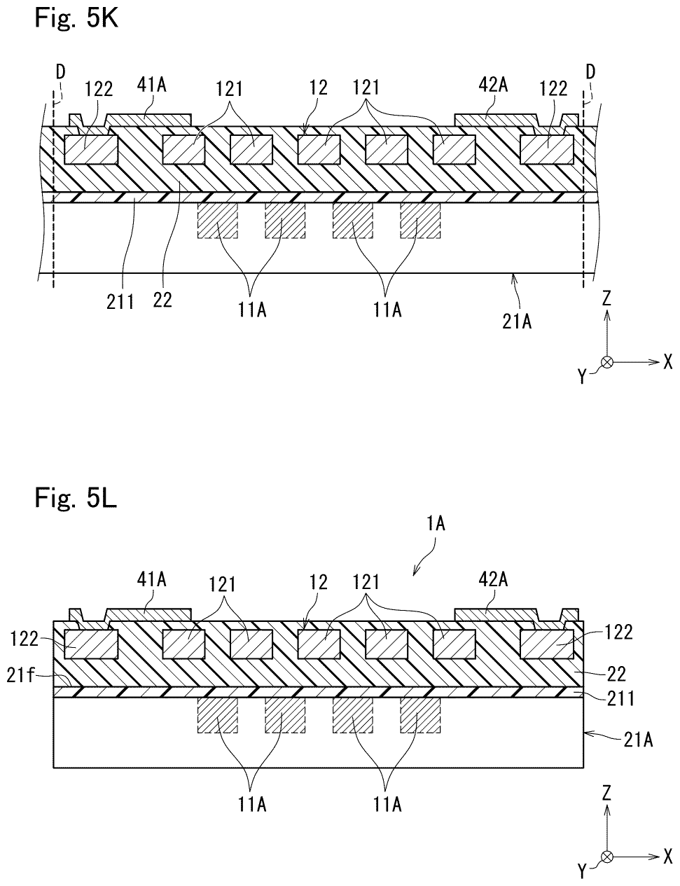

A method for producing the inductor component 1A will then be described. FIGS. 5A to 5G correspond to the IVA-IVA section (FIG. 4A) of FIG. 3, while FIGS. 5H to 5L correspond to the IVB-IVB section (FIG. 4B) of FIG. 3.

As shown in FIG. 5A, a semiconductor substrate 21a with the main surface 21f is prepared. In the following, for simplification of explanations, the semiconductor substrate 21a will be described as a silicon substrate.

As shown in FIG. 5B, the main surface 21f is patterned with a resist 75 and is doped with an impurity such as phosphine (PH₃). The patterned shape is a shape corresponding to the shape of the first inductor wire 11A. As a result, a doped layer 111A is formed at the main surface 21f. The doped layer 111A contains a semiconductor material of the semiconductor substrate 21a and is lower in electrical resistance than the semiconductor substrate 21a, the doped layer 111A being integrated with the semiconductor substrate 21a.

As shown in FIG. 5C, the semiconductor substrate 21a is thermally oxidized to form the insulating portion 211 that is a thermal oxide silicon layer at the main surface 21f. This thermal oxidation allows formation of the first inductor wire 11A extending through the interior of the semiconductor substrate 21a along the main surface 21f.

As shown in FIG. 5D, a photolithography process is used to form an opening 211a on the insulating portion 211 at a predetermined position so that the top surface of the first inductor wire 11A is partly exposed. The predetermined position is a position where the second connecting wire 52 is disposed. Etching in the photolithography process can be a dry etching method or a wet etching method.

As shown in FIG. 5E, a first layer of an insulating layer 221 is applied on the insulating portion 211 and cured. Afterward, the photolithography process is used to form an opening 221a on the first insulating layer 221 at a predetermined position so that the top surface of the first inductor wire 11A is partly exposed. The predetermined position is a position where the second connecting wire 52 is disposed.

As shown in FIG. 5F, a seed layer (not shown in FIG. 5F) is formed on the first inductor wire 11A. Subsequently, the resist 75 is applied and formed into a predetermined pattern using the photolithography process. The predetermined pattern is a pattern corresponding to the shape of the second inductor wire 12. While feeding the seed layer with electricity, an electrolytic plating method is used to form the second connecting wire 52 and the second inductor wire 12 at the same time on the first inductor wire 11A. Subsequently, the dry film resist (DFR) is stripped to etch the seed layer. After the formation of the second connecting wire 52, electrolytic plating may be again performed to form the second inductor wire 12.

As shown in FIG. 5G, a second layer of an insulating layer 222 is applied on the second inductor wire 12 and the first insulating layer 221 and cured. Consequently, the first insulating layer 221 and the second insulating layer 222 are stacked together so that the insulating layer 22 is formed.

As shown in FIG. 5H, the photolithography process is used to form the opening 22b on the insulating layer 22 at predetermined positions so that the top surface of the pad portion 122 of the second inductor wire 12 is partly exposed. The predetermined positions are positions of connection between the second inductor wire 12 and the first and second external terminals 41A and 42A.

As shown in FIG. 5I, the first external terminal 41A and the second external terminal 42A are formed by non-electrolytic plating so as to cover the top surface of the pad portion 122 of the second inductor wire 12 exposed from the insulating layer 22. The first external terminal 41A and the second external terminal 42A are, for example, Ni/Au stacked in order from the main surface 21f side. The non-electrolytic plating may use a catalyst such as Pb. The first external terminal 41A and the second external terminal 42A may be made of a combination of Cu/Ni/Au, Ni/Pd/Au, or Ni/Sn, or a single conductor such as Cu only, or may be made partly of a combination of alloys or an electrically conductive resin such as Ag paste.

As shown in FIG. 5J, the underside of the semiconductor substrate 21a is polished. This allows formation of the semiconductor substrate 21A whose thickness is adjusted. Polishing may be carried out using a chemical dry etching method or wet etching method, or may be achieved through mechanical polishing or grinding, or may be performed using a chemical method and a mechanical method like chemical mechanical polishing (CMP). Instead of polishing at this step, the semiconductor substrate may be polished together with mold resin, after mounting the inductor component.

As shown in FIG. 5K, when separated along cutting lines D into individual inductor components, the inductor component 1A is produced as shown in FIG. 5L.

### Third Embodiment

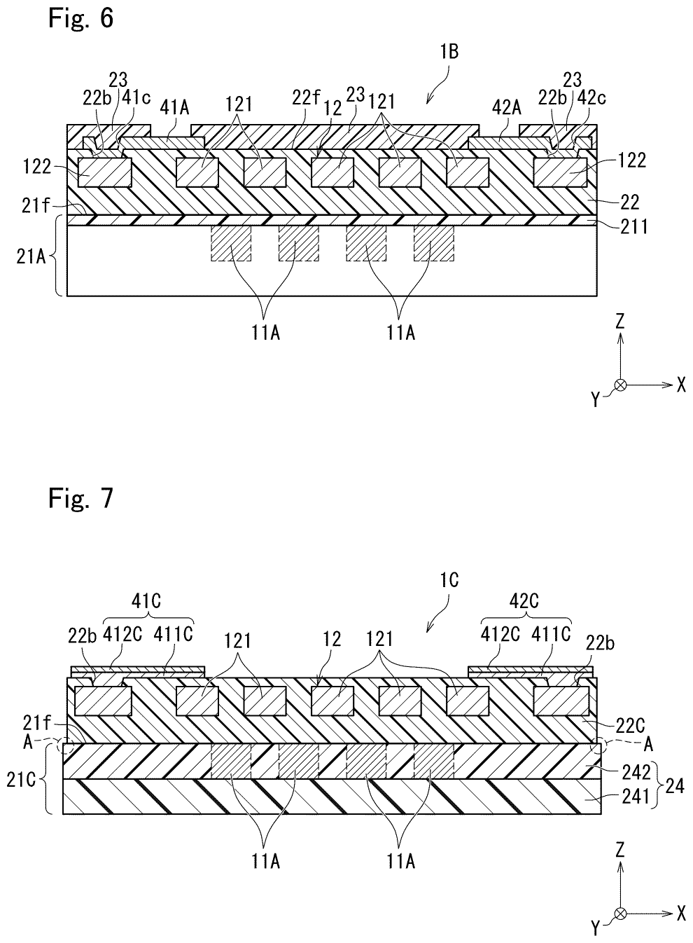

FIG. 6 is a cross-sectional view showing a third embodiment of the inductor component. FIG. 6 corresponds to FIG. 4B. The third embodiment differs from the second embodiment in that an overlayer is disposed. This different configuration will hereinafter be described. In the third embodiment, the same reference numerals as in the second embodiment designate the same configuration elements as those in the second embodiment and therefore will not again be described.

As shown in FIG. 6, an inductor component 1B includes an overlayer 23 that covers: a top surface 22f of the insulating layer 22; and a part of the external surface of the first external terminal 41A and a part of the external surface of the second external terminal 42A. Specifically, the overlayer 23 covers at least: the entire region of the top surface 22f of the insulating layer 22 except for regions where the first and the second external terminals 41A and 42A are disposed; and positions of recesses 41c and 42c corresponding to the openings 22b of the insulating layer 22, formed on the external surfaces of the first and the second external terminals 41A and 42A. The overlayer 23 is, for example, a solder resist whose main component is epoxy resin.

According to this embodiment, even though the recesses 41c and 42c lie on the external surfaces of the first and the second external terminals 41A and 42A, respectively, solder paste or solder balls can be placed on the external surfaces of the first and the second external terminals 41A and 42A, not covered by the overlayer 23, with the recesses 41c and 42c covered by the overlayer 23. That is, solder paste or solder balls can be placed avoiding the recesses 41c and 42c. This facilitates soldering.

### Fourth Embodiment

FIG. 7 is a cross-sectional view showing a fourth embodiment of the inductor component. FIG. 7 corresponds to FIG. 4B. The fourth embodiment differs from the second embodiment in the configuration of the semiconductor substrate, the configuration of the insulating layer, and the configuration of the external terminal. These different configurations will hereinafter be described. In the fourth embodiment, the same reference numerals as in the second embodiment designate the same configuration elements as those in the second embodiment and therefore will not again be described.

### Configuration

As shown in FIG. 7, a semiconductor substrate 21C includes an insulating portion 24 of a semiconductor material turned into an insulator. The insulating portion 24 includes a first-layered insulating portion 241 and a second-layered insulating portion 242. The second-layered insulating portion 242 is disposed on the first-layered insulating portion 241. The first inductor wires 11A are disposed within the second-layered insulating portion 242. The undersides of the first inductor wires 11A are in contact with the top surface of the first-layered insulating portion 241, while the top surfaces of the first inductor wires 11A are exposed from the top surface of the second-layered insulating portion 242. The semiconductor substrate 21C can be produced using e.g. a silicon-on-insulator (SOI) substrate. In this case, the first-layered insulating portion 241 contains a semiconductor material of the semiconductor substrate 21C, for example, Si, turned into an insulator, and is a buried-oxide (BOX) layer of e.g. a silicon oxide film. The second-layered insulating portion 242 is e.g. a silicon oxide film. This enables the resistivity of the semiconductor substrate 21C to increase to 10¹² Ω·cm, in comparison with the resistivity of the Si semiconductor substrate of the order of 10³ Ω·cm.

As indicated by reference sign A of FIG. 7, the insulating layer 22C is positioned inside of the outer edge of the main surface 21f, when viewed from the direction (Z direction) orthogonal to the main surface 21f of the semiconductor substrate 21C. Hence, when separated into individual inductor components 1C, the insulating layer 22C can be restrained from coming into contact with a cutting blade. Then, a resin of the insulating layer cannot be clogged over the cut line of the cutting blade. This facilitates separation into individual inductor components 1C.

The first external terminal 41C includes a Cu plating layer 411C and an Au plating layer 412C that are stacked in the mentioned order. The second external terminal 42C includes a Cu plating layer 421C and an Au plating layer 422C that are stacked in the mentioned order. However, this configuration is not limitative, and the Au plating layers 412C and 422C may each be substituted by e.g. an Ni plating layer. By imparting the two-layered configuration to the first and the second external terminals 41C and 42C, with the first layer of the Cu plating layer, as in this embodiment, it is possible to suppress the occurrence of depressions which may be formed, arising from the opening 22b of the insulating layer 22C, on the outer surfaces of the first and the second external terminals 41C and 42C.

According to this embodiment, since the semiconductor substrate 21C includes the insulating portion 24, the electrical resistance of the semiconductor substrate 21C increases. As a result, eddy currents can be reduced, leading to improved Q factor.

Preferably, the semiconductor substrate 21C is composed only of the first inductor wires 11A and the insulating portion 24. This configuration achieves further reduction in the eddy currents and therefore further improvement in Q factor.

### Production Method

An example of a method for producing the semiconductor substrate 21C will hereinafter be described.

First, a groove pattern is formed on a silicon substrate using photolithography method and etching method. A silicon oxide film is formed in the groove pattern using chemical vapor deposition (CVD) method, after which an unnecessary silicon oxide film is removed. Next, the first inductor wire 11A is formed with impurity doping in the same manner as in the second embodiment. In this case, use of a silicon-on-insulator (SOI) substrate as the silicon substrate allows a part or all of the portion of the silicon substrate except for the first inductor wires 11A to be a silicon oxide film and a BOX layer.

### Fifth Embodiment

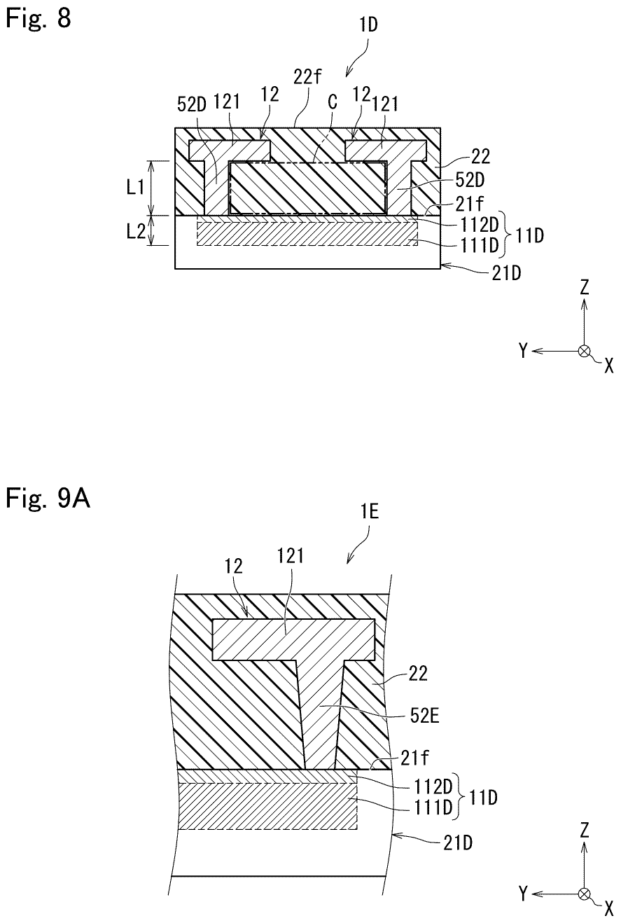

FIG. 8 is a cross-sectional view showing a fifth embodiment of the inductor component. FIG. 8 corresponds to FIG. 4A. The fifth embodiment differs from the second embodiment in the configurations of the semiconductor substrate and the second connecting wire. These different configurations will hereinafter be described. In the fifth embodiment, the same reference numerals as in the second embodiment designate the same configuration elements as those in the second embodiment and therefore the explanations thereof will be omitted.

As shown in FIG. 8, a first inductor wire 11D is at least partially silicidized. Specifically, the first inductor wire 11D includes a non-silicidized portion 111D and a silicidized portion 112D. The silicidized portion 112D can be formed, for example, by, after the formation of the first inductor wires, forming an Ni or other metal film on the doped region through sputtering or other method, and then by subjecting the metal film to heat treatment. The silicidized portion 112D has an electrical resistivity smaller than that of the non-silicidized portion 111D. The electrical resistivity of the silicidized portion 112D can be reduced to e.g. of the order of 10⁻⁵ Ω·m. This enables the entire first inductor wire 11D to have a reduced electrical resistivity. The whole of the first inductor wire 11D may be silicidized.

A second connecting wire 52D is a vertical wire extending in the direction (Z direction) orthogonal to the main surface 21f of a semiconductor substrate 21D. Specifically, the second connecting wire 52D extends from the top surface of the first inductor wire 11D to the underside of the wiring portion 121 of the second inductor wire 12. The second connecting wire 52D is of a cylindrical shape. The second connecting wire 52D may include a seed layer at a portion in contact with the first inductor wire 11D. A thickness L1 of the second connecting wire 52D in Z direction is greater than a thickness L2 of the first inductor wire 11D in Z direction. The thicknesses L1 and L2 may be measured along a cross section orthogonal to the main surface 21f, passing through the central axis of the second connecting wire 52D, for example, as shown in FIG. 8. The thickness L2 may be measured in the same manner as in the first embodiment. An example of the method for producing the second connecting wire 52D may include, for example: forming a patterned resist on the semiconductor substrate 21D using the photolithography process; and forming the second connecting wire 52D in the resist opening by electrolytic plating.

According to this embodiment, since the thickness L1 of the second connecting wire 52D in Z direction is greater than the thickness L2 of the first inductor wire 11D in Z direction, the parasitic capacitance can be reduced between the first inductor wire 11D and the second inductor wire 12. In the case of the helical coil as in this embodiment, the thickness L1 greater than the thickness L2 enables the size of a core (designated at reference sign C in FIG. 8) to increase as compared with the case of the thickness L1 smaller than the thickness L2. This leads to improvement in inductance and Q factor.

### First Variant

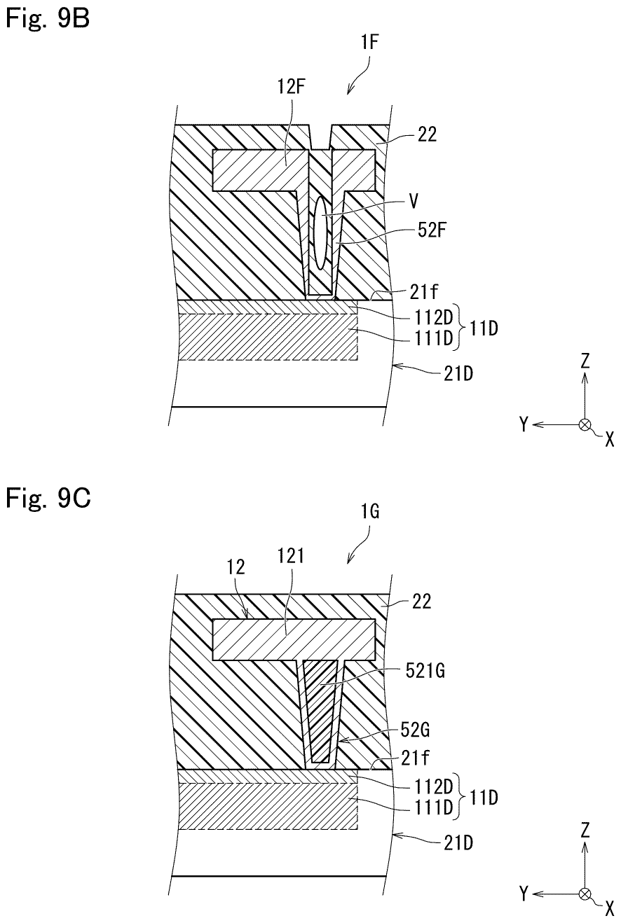

FIG. 9A is a partial cross-sectional view showing a second connecting wire 52E of an inductor component 1E according to a first variant. As shown in FIG. 9A, the second connecting wire 52E is of an inverted truncated conical shape. The second connecting wire 52E can be formed, for example, by, after formation of a first insulating layer as a part of the insulating layer 22, forming a through hole in the first insulating layer 22 with laser and then fill-plating the through hole.

### Second Variant

FIG. 9B is a partial cross-sectional view showing a second connecting wire 52F of an inductor component 1F according to a second variant. As shown in FIG. 9B, the second connecting wire 52F is hollow. The insulating layer 22 is present in a hollow portion. A void V is disposed within the insulating layer 22 present in the hollow portion. The void V can relieve the stress on the insulating layer 22. The second connecting wire 52F can be formed, for example, by, after formation of a first insulating layer as a part of the insulating layer 22, forming a through hole in the first insulating layer with laser and then applying conformal plating thereto.

### Third Variant

FIG. 9C is a partial cross-sectional view showing a second connecting wire 52G of an inductor component 1G according to a third variant. As shown in FIG. 9C, the second connecting wire 52G is electrically non-conductive at its central portion. Specifically, the second connecting wire 52G includes at its central portion a resin 521G that is an insulating resin. This can relieve the stress on the second connecting wire 52G. Alternatively, the electroconductive material at the central portion of the second connecting wire 52G may differ from that of the outer peripheral portion covering the outer circumference of the central portion. Specifically, the resin 521G may be an electrically conductive resin and may differ from the electroconductive material of the outer peripheral portion covering the circumference of the resin 521G. As a result, in the case of employing electrically conductive paste as the electroconductive material, the central portion of the second connecting wire 52G can be formed in a shortened time, facilitating production of the second connecting wire 52G.

### Sixth Embodiment

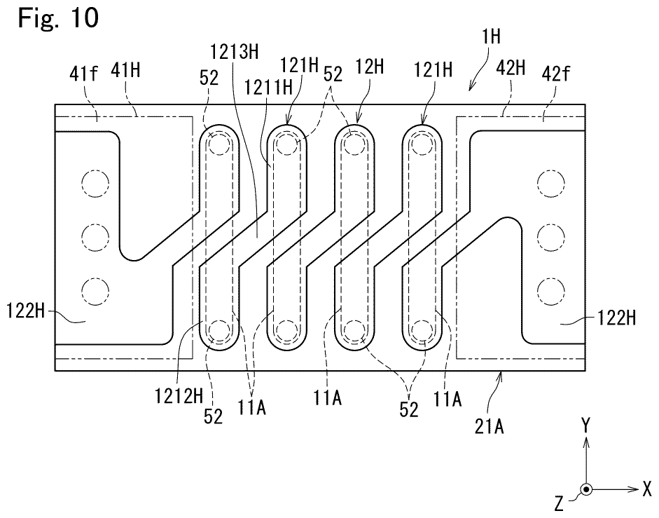

FIG. 10 is a top plan view showing a sixth embodiment of the inductor component. FIG. 10 corresponds to FIG. 3. The sixth embodiment differs from the second embodiment in the shape of the second inductor wire and the shape of the first and the second external terminals. These different configurations will hereinafter be described. In the sixth embodiment, the same reference numerals as in the second embodiment designate the same configuration elements as those in the second embodiment and therefore the explanations thereof will be omitted.

As shown in FIG. 10, the wire width at a part of the second inductor wire 12H in its extension direction differs from the wire width of the other portions. Specifically, the second inductor wire 12H includes a wiring portion 121H and a pad portion 122H. The wiring portion 121H is S-shaped when viewed from Z direction. The wiring portion 121H includes a first portion 1211H, a second portion 1212H, and a third portion 1213H. When viewed from Z direction, the first portion 1211H extends rectilinearly in Y direction from a first end lying on the forward Y direction side to a second end lying on slightly forward Y direction side with respect to the center of the semiconductor substrate 21A in Y direction. When viewed from Z direction, the second portion 1212H extends rectilinearly in Y direction from a first end lying on the reverse Y direction side to a second end lying on slightly reverse Y direction side with respect to the center of the semiconductor substrate 21A in Y direction. The third portion 1213H is connected to the second end of each of the first and the second portions 1211H and 1212H and, when viewed from Z direction, extends rectilinearly with a slight tilt in X direction. The first portion 1211H are equal in wire width to the second portion 1212H. The third portion 1213H has a wire width smaller than that of each of the first and the second portions 1211H and 1212H. This allows a part of the second inductor wire 12H in its extension direction to have a wire width different from the wire width of the other portions. “The part of the second inductor wire 12H in its extension direction” and “the other portions” of “the wire width of the other portions” described above exclude the pad portion 122H.

When viewed from Z direction, the pad portion 122H lying on the reverse X direction side has an edge on the reverse X direction side that overlaps with an edge on the reverse X direction side of the semiconductor substrate 21. When viewed from Z direction, the pad portion 122H lying on the forward X direction side has an edge on the forward X direction side that overlaps with an edge on the forward X direction side of the semiconductor substrate 21. This facilitates production of the pad portion 122H.

A first external terminal 41H has a terminal main surface 41f parallel to the main surface 21f, with its edge on the reverse X direction side overlapping with an edge on the reverse X direction side of the main surface 21f when viewed from Z direction. A second external terminal 42H has a terminal main surface 42f parallel to the main surface 21f, with its edge on the forward X direction side overlapping with an edge on the forward X direction side of the main surface 21f when viewed from Z direction. This facilitates production of the first and the second external terminals 41H and 42H.

According to this embodiment, since a part of the second inductor wire 12H differs in wire width from the other portions thereof, the freedom of design of the second inductor wire 12H increases. It is therefore easy to obtain a small-sized inductor component 1H or a high-inductance inductor 1H.

The present disclosure is not limited to the above embodiments, and can be changed in design without departing from the gist of the present disclosure. For example, their respective features of the first to sixth embodiments may variously be combined.

Although in the above embodiments, the inductor component includes the insulating layer and the external terminals disposed on the semiconductor substrate, the insulating layer and the external terminals are not essential configuration elements. If not disposed, the first inductor wire through the interior of the semiconductor substrate may directly connect to the external circuit when connecting the inductor component and the external circuit.

In the above embodiments, “inductor wiring” serves to generate magnetic flux when current flows, to thereby impart inductance to the inductor component, and therefore, no particular limitation is imposed on its structure, form, etc. Without being limited particularly to the straight line or curved line (spiral, or two-dimensional curve) extending on the plane as in the embodiments, various known wiring forms such as meander wiring can be used. The total number of the inductor wirings are not limited to one layer or two layers, and a multi-layer configuration including three or more layers may be employed. Although in the above embodiments, the shape of the first and the second connecting wires is circular when viewed from Z direction, it may be oval, elliptical, or rectangular.

Although in the above embodiments, the external terminals are disposed only on the top surface of the insulating layer, the positions to dispose the external terminals are not particularly limited. For example, the external terminals may be disposed only on the lateral surface or may be disposed on the top surface and lateral surface to be in an L shape.

Although in the first embodiment, only the first inductor wire is disposed as the inductor wiring, for example, a spiral second inductor wire may be disposed within the insulating layer and electrically connected to the first inductor wire.

(1) An inductor component comprising a semiconductor substrate made from a semiconductor material, the semiconductor substrate having a main surface; and a first inductor wire extending through the interior of the semiconductor substrate along the main surface. The first inductor wire contains the semiconductor material. Also, the first inductor wire has an electrical resistance lower than that of the semiconductor substrate and is integrated with the semiconductor substrate.

(2) The inductor component of (1), further comprising an insulating layer disposed on the main surface.

(3) The inductor component of (2), wherein when viewed from a direction orthogonal to the main surface, the insulating layer lies inside of an outer edge of the main surface.

(4) The inductor component of any one of (1) to (3), further comprising an external terminal electrically connected to the first inductor wire. The external terminal has a terminal main surface parallel to the main surface.

(5) The inductor component of (4), wherein when viewed from a direction orthogonal to the main surface, the external terminal lies inside of an outer edge of the main surface.

(6) The inductor component of (4) or (5), further comprising an overlayer partly covering an outer surface of the external terminal.

(7) The inductor component of any one of (4) to (6), further comprising a first connecting wire made from a metal material. The first connecting wire extends in a direction orthogonal to the main surface, to connect the external terminal and the first inductor wire.

(8) The inductor component of (7), wherein the first connecting wire has an electrically non-conductive central portion.

(9) The inductor component of (7), wherein the first connecting wire has an electrically conductive central portion made of an electroconductive material. The electroconductive material of the central portion differs from that of an outer peripheral portion covering an outer circumference of the central portion.

(10) The inductor component of any one of (1) to (9), wherein a part of the first inductor wire in its extension direction has a wire width different from that of the other portions.

(11) The inductor component of any one of (1) to (10), further comprising a second inductor wire disposed above the main surface. The second inductor wire is made from a metal material, and the second inductor wire is electrically connected to the first inductor wire.

(12) The inductor component of (11), further comprising a second connecting wire made from a metal material. The second connecting wire extends in a direction orthogonal to the main surface, and the second connecting wire connects the first inductor wire and the second inductor wire.

(13) The inductor component of (12), wherein the second connecting wire has an electrically non-conductive central portion.

(14) The inductor component of (12), wherein the second wire has an electrically conductive central portion made from an electroconductive material. The electroconductive material of the central portion differs from that of an outer peripheral portion covering an outer circumference of the central portion.

(15) The inductor component of any one of (12) to (14), comprising a plurality of the first inductor wires, a plurality of the second inductor wires, and a plurality of the second connecting wires. The first inductor wire, the second connecting wire, and the second inductor wire are connected in the mentioned order, to make up a coil whose winding axis is parallel to the main surface.

(16) The inductor component of any one of (1) to (15), further comprising a magnetic layer made from a magnetic material, the magnetic layer disposed above the first inductor wire.

(17) The inductor component of any one of (1) to (14), wherein the first inductor wire extends in a spiral shape.

(18) The inductor component of any one of (1) to (17), further comprising an insulating portion made from the semiconductor material turned into an insulator.

(19) The inductor component of any one of (1) to (18), wherein the first inductor wire is at least partly silicidized.

What is claimed is:

1. An inductor component comprising:
a semiconductor substrate including a semiconductor material, the semiconductor substrate having a main surface; and
a first inductor wire extending through the interior of the semiconductor substrate along the main surface,
the first inductor wire containing the semiconductor material, and
the first inductor wire having an electrical resistance lower than that of the semiconductor substrate and being integrated with the semiconductor substrate.

2. The inductor component of claim 1, further comprising:
an insulating layer on the main surface.

3. The inductor component of claim 2, wherein
when viewed from a direction orthogonal to the main surface, the insulating layer is inside of an outer edge of the main surface.

4. The inductor component of claim 1, further comprising:
an external terminal electrically connected to the first inductor wire, wherein
the external terminal has a terminal main surface parallel to the main surface.

5. The inductor component of claim 4, wherein
when viewed from a direction orthogonal to the main surface, the external terminal is inside of an outer edge of the main surface.

6. The inductor component of claim 4, further comprising:
an overlayer partly covering an outer surface of the external terminal.

7. The inductor component of claim 4, further comprising:
a first connecting wire including a metal material, the first connecting wire extending in a direction orthogonal to the main surface, to connect the external terminal and the first inductor wire.

8. The inductor component of claim 7, wherein
the first connecting wire has an electrically non-conductive central portion.

9. The inductor component of claim 7, wherein
the first connecting wire has an electrically conductive central portion including an electroconductive material, the electroconductive material of the central portion differing from that of an outer peripheral portion covering an outer circumference of the central portion.

10. The inductor component of claim 1, wherein
a part of the first inductor wire in its extension direction has a wire width different from that of the other portions.

11. The inductor component of claim 1, further comprising:
a second inductor wire above the main surface,
the second inductor wire including a metal material, and the second inductor wire being electrically connected to the first inductor wire.

12. The inductor component of claim 11, further comprising:
a second connecting wire including a metal material, the second connecting wire extending in a direction orthogonal to the main surface, and the second connecting wire connecting the first inductor wire and the second inductor wire.

13. The inductor component of claim 12, wherein
the second connecting wire has an electrically non-conductive central portion.

14. The inductor component of claim 12, wherein
the second wire has an electrically conductive central portion including an electroconductive material, the electroconductive material of the central portion differing from that of an outer peripheral portion covering an outer circumference of the central portion.

15. The inductor component of claim 12, comprising:
a plurality of the first inductor wires, a plurality of the second inductor wires, and a plurality of the second connecting wires, wherein
the first inductor wire, the second connecting wire, and the second inductor wire are connected in the mentioned order, to configure a coil whose winding axis is parallel to the main surface.

16. The inductor component of claim 1, further comprising:
a magnetic layer including a magnetic material, the magnetic layer being above the first inductor wire. insulator.

17. The inductor component of claim 1, wherein
the first inductor wire extends in a spiral shape.

18. The inductor component of claim 1, further comprising:
an insulating portion including the semiconductor material configured as an

19. The inductor component of claim 1, wherein
the first inductor wire is at least partly silicidized.

20. The inductor component of claim 2, further comprising:
an external terminal electrically connected to the first inductor wire, wherein
the external terminal has a terminal main surface parallel to the main surface.
